(19) United States
(12) Patent Application Publication
(10) Pub. No.: US 2026/0312854 A1
(43) Pub. Date: Oct. 8, 2026

(54) RADIO FREQUENCY BAND SWITCHING IN A POWER MANAGEMENT INTEGRATED CIRCUIT

(71) Applicant: Qorvo US, Inc., Greensboro, NC (US)

(72) Inventors: Jean-Frederic Chiron, Tournefeuille (FR); Nadim Khlat, Ceret (FR); Christopher Truong Ngo, Queen Creek, AZ (US)

(21) Appl. No.: 19/476,369

(22) PCT Filed: Apr. 24, 2024
(86) PCT No.: PCT/US2024/025957

§ 371 Date: Oct. 17, 2025

Related U.S. Application Data
(60) Provisional application No. 63/501,279, filed on May 10, 2023.

(51) Int. Cl. H04L 27/26; G05F 1/46; H04B 1/00; H04B 1/04; H04B 1/40

(52) U.S. Cl. CPC H04L 27/2627; G05F 1/46; H04B 1/0067; H04B 1/40; H04B 2001/0408; H04B 1/0475

(57) ABSTRACT

Radio frequency (RF) band switching in a power management integrated circuit (PMIC) is provided. Herein, the PMIC is configured to adapt a modulated voltage to amplify an RF signal for transmission in different RF bands. In embodiments disclosed herein, a band-switching circuit in the PMIC is configured to receive a band-switching indication to switch from a current RF band to a different RF band. Accordingly, the band-switching circuit can cause the PMIC to reload a corresponding set of parameters to thereby adapt the modulated voltage for the different RF band within a defined switching interval (e.g., <5 μs). As a result, the PMIC can be flexibly configured to adapt the modulated voltage between multiple RF bands under ever stringent switching delay requirements.

### RELATED APPLICATIONS

This application claims the benefit of U.S. provisional patent application Ser. No. 63/501,279, filed on May 10, 2023, the disclosure of which is hereby incorporated herein by reference in its entirety.

### FIELD OF THE DISCLOSURE

The technology of the disclosure relates generally to a power management integrated circuit (PMIC) configured to adapt a modulated voltage to amplify a radio frequency (RF) signal for transmission in different RF bands.

### BACKGROUND

Fifth generation (5G) new radio (NR) (5G-NR) has been widely regarded as the next generation of wireless communication technology beyond the current third generation (3G) and fourth generation (4G) technologies. In this regard, a wireless communication device capable of supporting the 5G-NR wireless communication technology is expected to achieve higher data rates, improved coverage range, enhanced signaling efficiency, and reduced latency.

Downlink and uplink transmissions in a 5G-NR system are widely based on orthogonal frequency division multiplexing (OFDM) technology. In an OFDM based system, physical radio resources are divided into a number of subcarriers in a frequency domain and a number of OFDM symbols in a time domain. The subcarriers are orthogonally separated from each other by a subcarrier spacing (SCS). The OFDM symbols are separated from each other by a cyclic prefix (CP), which acts as a guard band to help overcome inter-symbol interference (ISI) between the OFDM symbols.

A radio frequency (RF) signal communicated in the OFDM based system is often modulated into multiple subcarriers in the frequency domain and multiple OFDM symbols in the time domain. The multiple subcarriers occupied by the RF signal collectively define a modulation bandwidth of the RF signal. The multiple OFDM symbols, on the other hand, define multiple time intervals during which the RF signal is communicated. In the 5G-NR system, the RF signal is typically modulated with a high modulation bandwidth in excess of 200 MHz.

The duration of an OFDM symbol depends on the SCS and the modulation bandwidth. The table below (Table 1) provides some OFDM symbol durations, as defined by 3G partnership project (3GPP) standards for various SCSs and modulation bandwidths. Notably, the higher the modulation bandwidth is, the shorter the OFDM symbol duration will be. For example, when the SCS is 120 KHz and the modulation bandwidth is 400 MHz, the OFDM symbol duration is 8.93 μs.

TABLE 1

| | | # of | | OFDM | |
|---|---|---|---|---|---|
| | Slot | Slots | | Symbol | Modulation |
| SCS | Length | per | CP | Duration | Bandwidth |
| (KHz) | (μs) | Subframe | (μs) | (μs) | (MHz) |
| 15 | 1000 | 1 | 4.69 | 71.43 | 50 |
| 30 | 500 | 2 | 2.34 | 35.71 | 100 |
| 60 | 250 | 4 | 1.17 | 17.86 | 200 |
| 120 | 125 | 8 | 0.59 | 8.93 | 400 |

In a 5G-NR system, the RF signal can be modulated with a time-variant power that changes from one OFDM symbol to another. In this regard, a power amplifier circuit(s) is required to amplify the RF signal to a certain power level within each OFDM symbol duration. Such inter-symbol power variation creates a unique challenge for a power management integrated circuit (PMIC) because the PMIC must be able to adapt a modulated voltage supplied to the power amplifier circuit within a very short voltage switching interval (e.g., the CP of each OFDM symbol) to help avoid distortion (e.g., amplitude clipping) in the RF signal.

Further, the PMIC may also need to adapt the modulated voltage between different RF bands. Understandably, the PMIC may have to generate the modulated voltage for different RF bands based on different configuration parameters. As such, it is desirable to switch the configuration parameters in a timely manner to ensure that the PMIC can adapt the modulated voltage within the very short voltage switching interval.

### SUMMARY

Embodiments of the disclosure relate to radio frequency (RF) band switching in a power management integrated circuit (PMIC). Herein, the PMIC is configured to adapt a modulated voltage to amplify an RF signal for transmission in different RF bands. In embodiments disclosed herein, a band-switching circuit in the PMIC is configured to receive a band-switching indication to switch from a current RF band to a different RF band. Accordingly, the band-switching circuit can cause the PMIC to reload a corresponding set of parameters to thereby adapt the modulated voltage for the different RF band within a defined switching interval (e.g., <5 μs). As a result, the PMIC can be flexibly configured to adapt the modulated voltage between multiple RF bands under ever stringent switching delay requirements.

In one aspect, a PMIC is provided. The PMIC includes a voltage processing circuit. The voltage processing circuit is configured to generate a modulated voltage based on a first parameter set predefined for a first RF band and a second parameter set predefined for a second RF band different from the first RF band. The PMIC also includes a band-switching circuit. The band-switching circuit is configured to receive a band-switching indication to switch from a first one of the first RF band and the second RF band to a second one of the first RF band and the second RF band. The band-switching circuit is also configured to cause the voltage processing circuit to switch from generating the modulated voltage based on one of the first parameter set and the second parameter set predefined for the first one of the first RF band and the second RF band to generating the modulated voltage based on another one of the first parameter set and the second parameter set predefined for the second one of the first RF band and the second RF band within a defined switching interval.

In another aspect, a wireless device is provided. The wireless device includes one or more PMICs. Each of the one or more PMICs includes a voltage processing circuit. The voltage processing circuit is configured to generate a modulated voltage based on a first parameter set predefined for a first RF band and a second parameter set predefined for a second RF band different from the first RF band. Each of the one or more PMICs also includes a band-switching circuit. The band-switching circuit is configured to receive a band-switching indication to switch from a first one of the first RF band and the second RF band to a second one of the first RF band and the second RF band. The band-switching circuit is also configured to cause the voltage processing circuit to switch from generating the modulated voltage based on one of the first parameter set and the second parameter set predefined for the first one of the first RF band and the second RF band to generating the modulated voltage based on another one of the first parameter set and the second parameter set predefined for the second one of the first RF band and the second RF band within a defined switching interval.

In another aspect, a method for switching RF bands in a wireless device is provided. The method includes generating a modulated voltage based on a first parameter set predefined for a first RF band and a second parameter set predefined for a second RF band different from the first RF band. The method also includes receiving a band-switching indication to switch from a first one of the first RF band and the second RF band to a second one of the first RF band and the second RF band. The method also includes switching from generating the modulated voltage based on one of the first parameter set and the second parameter set predefined for the first one of the first RF band and the second RF band to generating the modulated voltage based on another one of the first parameter set and the second parameter set predefined for the second one of the first RF band and the second RF band within a defined switching interval.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary wireless communication circuit wherein a power management integrated circuit (PMIC) is configured according to an embodiment of the present disclosure to quickly adapt a modulated voltage between different radio frequency (RF) bands based on different parameter sets;

FIG. 2A is a graphic diagram illustrating a hot voltage switching scheme that can be employed by the PMIC in FIG. 1 to quickly adapt the modulated voltage;

FIG. 2B is a graphic diagram illustrating a cold voltage switching scheme that can be employed by the PMIC in FIG. 1 to quickly adapt the modulated voltage;

FIG. 3 is a schematic diagram of an exemplary band-switching circuit that can be provided in the PMIC in FIG. 1 to enable quick adaptation of the modulated voltage;

FIG. 4 is a schematic diagram of an exemplary wireless communication circuit configured to include multiple PMICs each configured according to the embodiment of FIG. 1;

FIG. 5 is a schematic diagram of an exemplary communication device wherein the wireless communication circuit of FIGS. 1 and 4 can be provided; and

FIG. 6 is a flowchart of an exemplary process for switching RF bands in the wireless communication circuits of FIGS. 1 and 4.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to radio frequency (RF) band switching in a power management integrated circuit (PMIC). Herein, the PMIC is configured to adapt a modulated voltage to amplify an RF signal for transmission in different RF bands. In embodiments disclosed herein, a band-switching circuit in the PMIC is configured to receive a band-switching indication to switch from a current RF band to a different RF band. Accordingly, the band-switching circuit can cause the PMIC to reload a corresponding set of parameters to thereby adapt the modulated voltage for the different RF band within a defined switching interval (e.g., <5 μs). As a result, the PMIC can be flexibly configured to adapt the modulated voltage between multiple RF bands under ever stringent switching delay requirements.

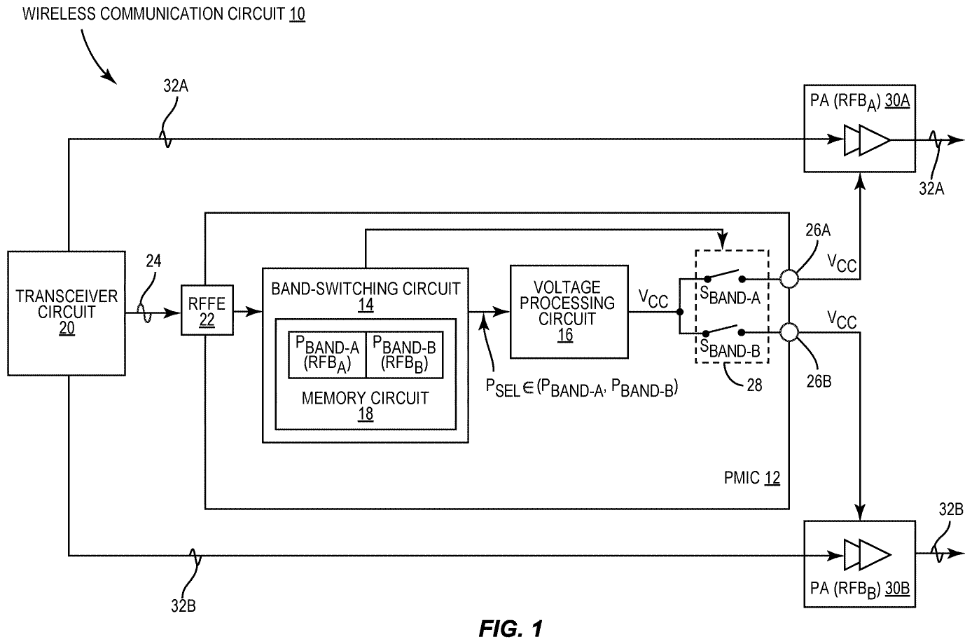

FIG. 1 is a schematic diagram of an exemplary wireless communication circuit 10 wherein a PMIC 12 is configured to quickly adapt a modulated voltage V_{CC} (e.g., an envelope tracking voltage or an average power tracking voltage) between different RF bands based on different parameter sets. In an embodiment, the PMIC 12 includes a band-switching circuit 14 and a voltage processing circuit 16. As described in detail below, the different parameter sets (referred to interchangeably as “a first parameter set P_{BAND-A}” and “a second parameter set P_{BAND-B}” hereinafter) are predefined for the different RF bands (referred interchangeably as “a first RF band RFB_{A}” and “a second RF band RFB_{B}” hereinafter), respectively. Each of the first parameter set P_{BAND-A} and the second parameter set P_{BAND-B} can include one or more parameters that will configure the voltage processing circuit 16 to generate the modulated voltage V_{CC} for a respective one of the first RF band RFB_{A} and the second RF band RFB_{B}.

In a non-limiting example, the first RF band RFB_{A} can be a time-division duplex (TDD) band 78 and the second RF band RFB_{B} can be a frequency-division duplex (FDD) band 3, or vice versa. Understandably, the first RF band RFB_{A} and the second RF band RFB_{B} can be any other RF band combinations as defined by regulatory authorities, industry groups, and/or standard organizations.

The first parameter set P_{BAND-A} and the second parameter set P_{BAND-B} are preloaded into a memory circuit 18, which may be provided in the band-switching circuit 14 or elsewhere in the PMIC 12. In an embodiment, the first parameter set P_{BAND-A} and the second parameter set P_{BAND-B} may be preloaded into the memory circuit 18 by a transceiver circuit 20 over an RF front-end (RFFE) interface 22 using an RFFE extended register write command sequence as defined in the MIPI® Alliance RFFE specification.

Notably, it can take as much as forty-five microseconds (45 μs) to load any of the first parameter set P_{BAND-A} and the second parameter set P_{BAND-B} from the transceiver circuit 20 to the PMIC 12 over the RFFE interface 22. In this regard, if the first parameter set P_{BAND-A} or the second parameter set P_{BAND-B} is transferred dynamically from the transceiver circuit 20 to the PMIC 12 in response to a switch between the first RF band RFB_{A} and the second RF band RFB_{B}, it will not be possible to adapt the modulated voltage V_{CC} under ever stringent switching delay requirements. In contrast, by preloading the first parameter set P_{BAND-A} and the second parameter set P_{BAND-B} into the memory circuit 18 based on the embodiments disclosed herein, the band-switching circuit 14 can quickly reconfigure the voltage processing circuit 16 based on a selected one of the first parameter set P_{BAND-A} and the second parameter set P_{BAND-B} in response to receiving a band-switching indication 24 to switch from the first RF band RFB_{A} to the second RF band RFB_{B}, or vice versa. As a result, the voltage processing circuit 16 can adapt the modulated voltage V_{CC} within a defined switching interval (e.g., <5 μs), thus making it possible for the PMIC 12 to support inter-symbol voltage adaptation, such as voltage adaptation in between two adjacent orthogonal frequency division multiplexing (OFDM) symbols.

Herein, the PMIC 12 can further include a first voltage output 26A, a second voltage output 26B, and a switch circuit 28. The first voltage output 26A may be coupled to a first power amplifier circuit 30A configured to amplify a first RF signal 32A based on the modulated voltage V_{CC} for transmission in the first RF band RFB_{A}. The second voltage output 26B may be coupled to a second power amplifier circuit 30B configured to amplify a second RF signal 32B based on the modulated voltage V_{CC} for transmission in the second RF band RFB_{B}. Both the first RF signal 32A and the second RF signal 32B are generated by the transceiver circuit 20.

In an embodiment, the switch circuit 28 includes a first switch S_{BAND-A} and a second switch S_{BAND-B}. The first switch S_{BAND-A} is coupled between the voltage processing circuit 16 and the first voltage output 26A and the second switch S_{BAND-B} is coupled between the voltage processing circuit 16 and the second voltage output 26B. When the first switch S_{BAND-A} is closed and the second switch S_{BAND-B} is opened, the modulated voltage V_{CC} is provided to the first power amplifier circuit 30A via the first voltage output 26A to thereby amplify the first RF signal 32A for transmission in the first RF band RFB_{A}. In contrast, when the first switch S_{BAND-A} is opened and the second switch S_{BAND-B} is closed, the modulated voltage V_{CC} is provided to the second power amplifier circuit 30B via the second voltage output 26B to thereby amplify the second RF signal 32B for transmission in the second RF band RFB_{B}.

In this regard, adapting the modulated voltage V_{CC} in response to switching between the first RF band RFB_{A} and the second RF band RFB_{B} would involve configuring the voltage processing circuit 16 based on a selected parameter set P_{SEL} (P_{SEL}∈(P_{BAND-A}, P_{BAND-B}) and toggling the first switch S_{BAND-A} and the second switch S_{BAND-B} appropriately. Moreover, the PMIC 12 must complete loading the selected parameter set P_{SEL} and toggling the first switch S_{BAND-A} and the second switch S_{BAND-B} all within the defined switching interval.

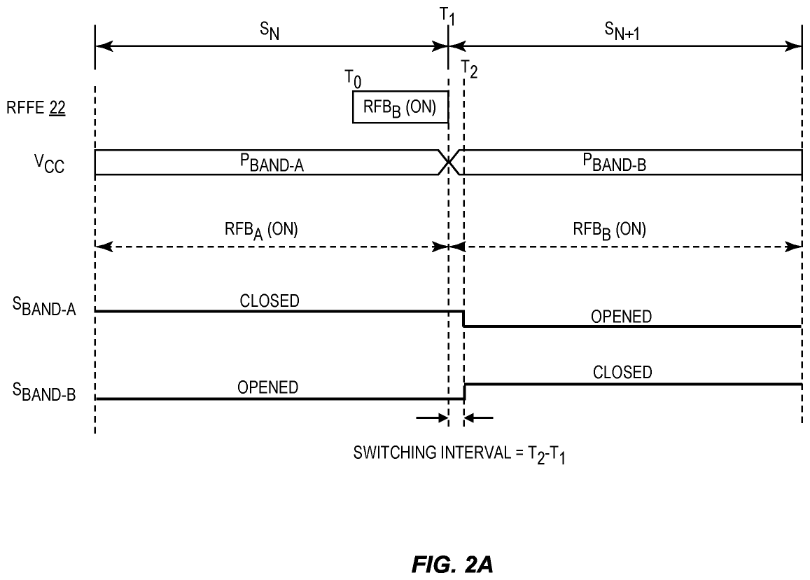

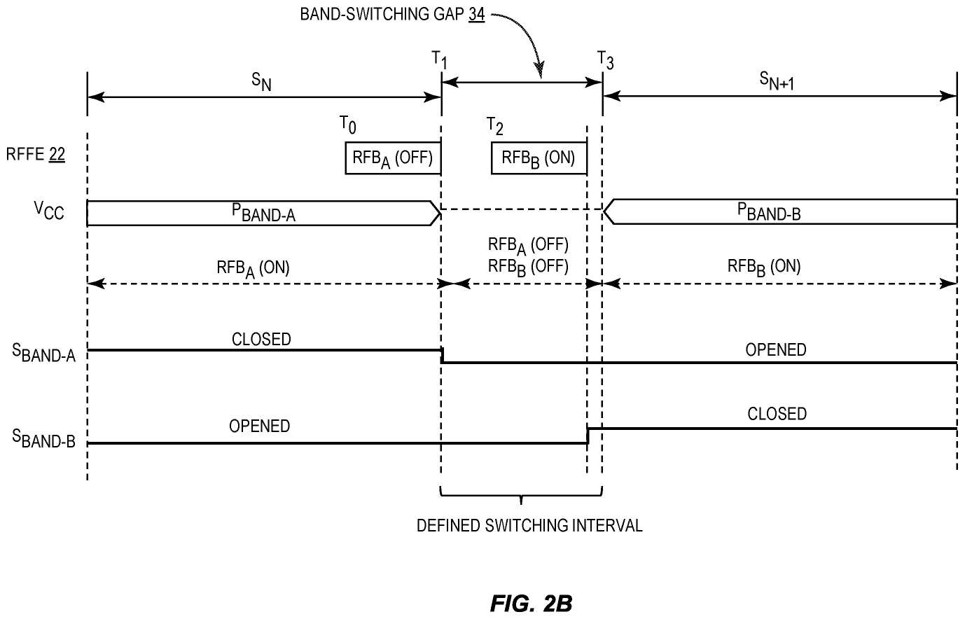

In one embodiment, the PMIC 12 can be configured to adapt the modulated voltage V_{CC} based on a hot voltage switching scheme, as illustrated in FIG. 2A. In this regard, FIG. 2A is a graphic diagram illustrating a hot voltage switching scheme that can be employed by the PMIC 12 in FIG. 1 to quickly adapt the modulated voltage V_{CC}. Common elements between FIGS. 1 and 2A are shown therein with common element numbers and will not be re-described herein.

Herein, the PMIC 12 is configured to adapt the modulated voltage V_{CC} in between two consecutive OFDM symbols S_{N}, S_{N+1}. For the purpose of distinction, the OFDM symbol S_{N} is referred to interchangeably as a “present OFDM symbol” and the OFDM symbol S_{N+1}, which immediately succeeds the OFDM symbol S_{N}, is referred to interchangeably as a “future OFDM symbol.”

In a non-limiting example, during the present OFDM symbol S_{N}, the first power amplifier circuit 30A is configured to amplify the first RF signal 32A for transmission in the first RF band RFB_{A} (RFB_{A} ON). Accordingly, the modulated voltage V_{CC} is generated based on the first parameter set P_{BAND-A}, the first switch S_{BAND-A} is closed to couple the voltage processing circuit 16 to the first voltage output 26A, and the second switch S_{BAND-B} is opened to decouple the voltage processing circuit 16 from the second voltage output 26B.

During the present OFDM symbol S_{N} (e.g., at time T₀), the band-switching circuit 14 receives the band-switching indication 24 that indicates a switch from the first RF band RFB_{A} in the present OFDM symbol S_{N} to the second RF band RFB_{B} in the future OFDM symbol S_{N+1}. Understandably, during the future OFDM symbol S_{N+1}, the modulated voltage V_{CC} needs to be generated based on the second parameter set P_{BAND-B}. Thus, as described earlier, the PMIC 12 must complete reloading the second parameter set P_{BAND-B}, opening the first switch S_{BAND-A}, and closing the second switch S_{BAND-B} all within the defined switching interval.

As such, the band-switching circuit 14 is configured to close the second switch S_{BAND-B} and open the first switch S_{BAND-A} concurrently at a start (i.e., time Ti) of the future OFDM symbol S_{N+1} to thereby decouple the voltage processing circuit 16 from the first voltage output 26A and couple the voltage processing circuit 16 to the second voltage output 26B. At time T₂, the band-switching circuit 14 must also complete reloading the second parameter set P_{BAND-B}. Depending on the exact size of the second parameter set P_{BAND-B}, the band-switching circuit 14 may start reloading the second parameter set P_{BAND-B} at or prior to the start (i.e., time T₁) of the future OFDM symbol S_{N+1}. Hence, the time T₂ and T₁ define an actual switching interval, which must be less than or equal to the defined switching interval. Thus, at time T₂, the voltage processing circuit 16 will generate the modulated voltage V_{CC} based on the second parameter set P_{BAND-B}, the first switch S_{BAND-A} is opened to decouple the voltage processing circuit 16 from the first voltage output 26A, the second switch S_{BAND-B} is closed to couple the voltage processing circuit 16 to the second voltage output 26B, and the second power amplifier circuit 30B is active to amplify the second RF signal 32B for transmission in the second RF band RFB_{B} (RFB_{B} ON).

In another embodiment, the PMIC 12 can be configured to adapt the modulated voltage V_{CC} based on a cold voltage switching scheme, as illustrated in FIG. 2B. FIG. 2B is a graphic diagram illustrating a cold voltage switching scheme that can be employed by the PMIC 12 in FIG. 1 to quickly adapt the modulated voltage V_{CC}. Common elements between FIGS. 1 and 2B are shown therein with common element numbers and will not be re-described herein.

Herein, the PMIC 12 is configured to adapt the modulated voltage V_{CC} in between two adjacent OFDM symbols S_{N}, S_{N+1} that are separated by a band-switching gap 34 (e.g., 5 μs). For the purpose of distinction, the OFDM symbol S_{N} is referred interchangeably as a “present OFDM symbol” and the OFDM symbol S_{N+1}, which immediately succeeds the OFDM symbol S_{N}, is referred interchangeably as a “future OFDM symbol.”

In a non-limiting example, during the present OFDM symbol S_{N}, the first power amplifier circuit 30A is configured to amplify the first RF signal 32A for transmission in the first RF band RFB_{A} (RFB_{A} ON). Accordingly, the modulated voltage V_{CC} is generated based on the first parameter set P_{BAND-A}, the first switch S_{BAND-A} is closed to couple the voltage processing circuit 16 to the first voltage output 26A, and the second switch S_{BAND-B} is opened to decouple the voltage processing circuit 16 from the second voltage output 26B.

During the present OFDM symbol S_{N} (e.g., at time T₀), the band-switching circuit 14 receives the band-switching indication 24 that indicates a switch-off of the first RF band RFB_{A} at an end (time T₁) of the present OFDM symbol S_{N}. Accordingly, the band-switching circuit 14 opens the first switch S_{BAND-A} at the end (time T₁) of the present OFDM symbol S_{N} to decouple the voltage processing circuit 16 from the first voltage output 26A. Notably, at time T₁, both the first switch S_{BAND-A} and the second switch S_{BAND-B} are open and, as a result, none of the first power amplifier circuit 30A and the second power amplifier circuit 30B is receiving the modulated voltage V_{CC}. In other words, there is no transmission in any of the first RF band RFB_{A} (RFB_{A} OFF) and the second RF band RFB_{B} (RFB_{B} OFF).

During the band-switching gap 34 (e.g., at time T₂), the band-switching circuit 14 receives the band-switching indication 24 that indicates a switch-on of the second RF band RFB_{B}. Accordingly, the band-switching circuit 14 starts configuring the voltage processing circuit 16 to generate the modulated voltage V_{CC} based on the second parameter set P_{BAND-B} and close the second switch S_{BAND-B} to couple the voltage processing circuit 16 to the second voltage output 26B. Understandably, the band-switching circuit 14 must complete reloading the second parameter set P_{BAND-B} and closing the second switch S_{BAND-B} at or prior to an end (e.g., Time T₃) of the band-switching gap 34 such that the second power amplifier circuit 30B can start amplifying the second RF signal 32B for transmission in the second RF band RFB_{B} (RFB_{B} ON) at a start (e.g., Time T₃) of the future OFDM symbol S_{N+1}. Herein, the band-switching gap 34 defines the defined switching interval.

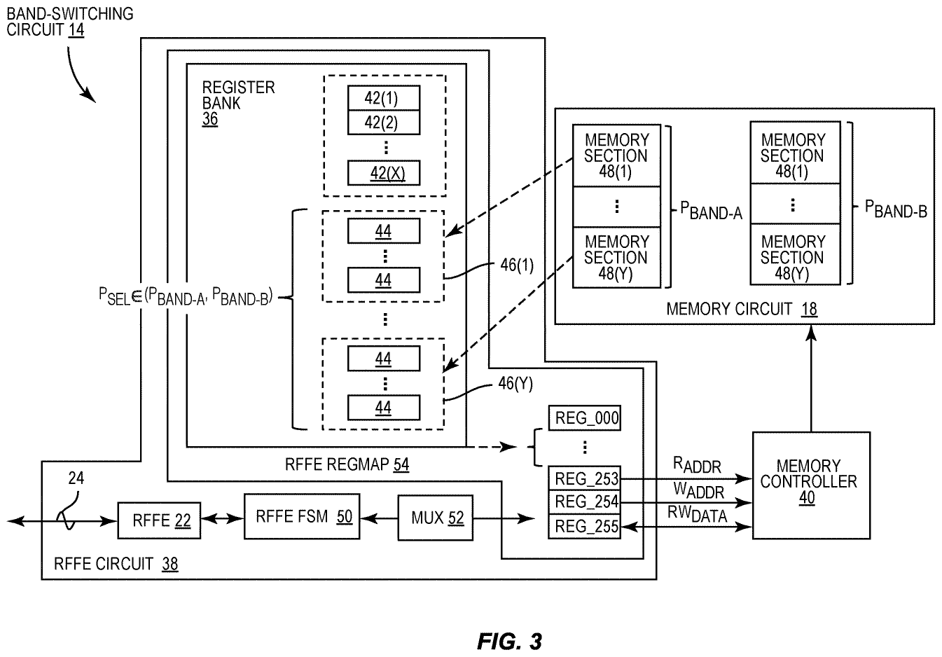

FIG. 3 is a schematic diagram providing an exemplary illustration of the band-switching circuit 14 in FIG. 1 configured according to an embodiment of the present disclosure. Common elements between FIGS. 1 and 3 are shown therein with common element numbers and will not be re-described herein.

In an embodiment, the band-switching circuit 14 includes a register bank 36, an RFFE circuit 38, and a memory controller 40. The register bank 36 includes one or more control registers 42(1)-42(X) and multiple configuration registers 44 organized into one or more parameter clusters 46(1)-46(Y). Herein, the control registers 42(1)-42(X) can be configured to store high level control information for the PMIC 12. As an example, the memory controller 40 can be configured to read the band-switching indication 24 out of the control registers 42(1)-42(X) and control the memory circuit 18 to load the selected parameter set P_{SEL} among the first parameter set P_{BAND-A} and the second parameter set P_{BAND-B} into the parameter clusters 46(1)-46(Y).

In a non-limiting example, each of the first parameter set P_{BAND-A} and the second parameter set P_{BAND-B} can include one or more parameter subsets 48(1)-48(Y). In this regard, the memory controller 40 is configured to load each of the parameter subsets 48(1)-48(Y) into a respective one of the parameter clusters 46(1)-46(Y). In an embodiment, the parameter subsets 48(1)-48(Y) can be loaded into the parameter clusters 46(1)-46(Y) simultaneously to help reduce loading time. The voltage processing circuit 16, in turn, reads the parameter subsets 48(1)-48(Y) from the parameter clusters 46(1)-46(Y) and generates the modulated voltage V_{CC} accordingly.

The RFFE circuit 38 is configured to preload the first parameter set P_{BAND-A} and the second parameter set P_{BAND-B} into the memory circuit 18 based on the RFFE extended register read/write command sequence. In a non-limiting example, the RFFE circuit 38 includes an RFFE finite-state-machine (FSM) 50, a multiplexer (MUX) 52, and a register map (REGMAP) 54. The RFFE extended register read/write command sequence, as defined in the MIPI® Alliance RFFE specification, has an address space of two-hundred fifty-six (256) registers, which are labeled from REG_000 to REG_255 in the REGMAP 54. Herein, the RFFE circuit 38 is configured to read or write the first parameter set P_{BAND-A} and the second parameter set P_{BAND-B} using the last three registers REG_253, REG_254, and REG_255 in the REGMAP 54. In an embodiment, the register bank 36 is part of the RFFE REGMAP 54. In other words, the register bank 36 can include any of the registers (except for the last three registers REG_253, REG_254, and REG_255) in the address space of the RFFE REGMAP 54.

Understandably, each of the first parameter set P_{BAND-A} and the second parameter set P_{BAND-B} needs to be written into the memory circuit 18 in multiple data bytes. In this regard, the register REG_254 may contain a write pointer indicating a starting address (denoted as W_{ADDR}) of the multiple data bytes to be written into the memory circuit 18. The register REG_255, on the other hand, is overwritten by the multiple data bytes (denoted as RW_{DATA}). The memory controller 40 reads each of the data bytes from the register REG_255 and writes each of the data bytes sequentially into an appropriate location in the memory circuit 18.

To read each of the first parameter set P_{BAND-A} and the second parameter set P_{BAND-B} from the memory circuit 18, the register REG_253 may contain a read pointer indicating a starting address (denoted as RADDR) of the multiple data bytes to be read from the memory circuit 18. The register REG_255, in this regard, is overwritten by the data bytes (denoted as RW_{DATA}) read from the memory circuit 18.

Given that the RFFE interface 22 is a serial data interface and each of the registers REG_000-REG_255 in the REGMAP 54 is a multi-bit register, the MUX 52 is configured to perform serial-to-parallel conversion during RFFE write and parallel-to-serial conversion during RFFE read. Given that the RFFE circuit 38 does perform RFFE write and RFFE read simultaneously, it is thus possible to share the MUX 52 between RFFE write and RFFE read to help reduce a footprint of the band-switching circuit 14.

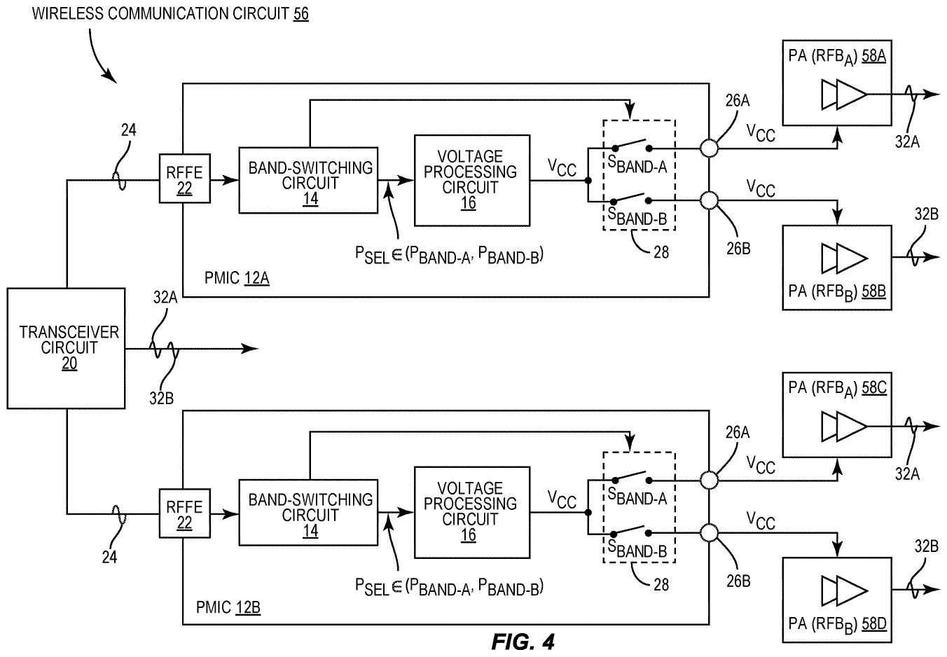

The wireless communication circuit 10 of FIG. 1 can be further configured to enable multiple-input, multiple-output (MIMO), dual-connectivity (DC), and/or licensed assisted access (LAA) operations. In this regard, FIG. 4 is a schematic diagram of an exemplary wireless communication circuit 56 including multiple PMICs 12A, 12B each configured in an identical fashion as the PMIC 12 in FIG. 1. Common elements between FIGS. 1 and 2A are shown therein with common element numbers and will not be re-described herein.

In one embodiment, the wireless communication circuit 56 can be configured to simultaneously amplify the first RF signal 32A using a pair of power amplifier circuits 58A, 58C for simultaneous MIMO transmission in the first RF band RFB_{A}. In this regard, the voltage processing circuit 14 in each of the PMICs 12A and 12B must simultaneously switch to generating the modulated voltage V_{CC} based on the first parameter set P_{BAND-A}. In other words, each of the PMICs 12A and 12B must simultaneously load the first parameter set P_{BAND-A} from the memory circuit 18 in FIG. 3 into the parameter clusters 46(1)-46(Y) in the register bank 36.

In another embodiment, the wireless communication circuit 56 can be configured to simultaneously amplify the second RF signal 32B using a pair of power amplifier circuits 58B, 58D for simultaneous MIMO transmission in the second RF band RFB_{B}. In this regard, the voltage processing circuit 14 in each of the PMICs 12A and 12B must simultaneously switch to generating the modulated voltage V_{CC} based on the second parameter set P_{BAND-B}. In other words, each of the PMICs 12A and 12B must simultaneously load the second parameter set P_{BAND-B} from the memory circuit 18 into the parameter clusters 46(1)-46(Y) in the register bank 36.

In another embodiment, the wireless communication circuit 56 can be configured to simultaneously amplify the first RF signal 32A and the second RF signal 32B using the power amplifier circuits 58A, 58B, the power amplifier circuits 58A, 58D, the power amplifier circuits 58B, 58C, or the power amplifier circuits 58C, 58D for simultaneous DC or LAA transmission in the first RF band RFB_{A} and the second RF band RFB_{B}. In this regard, one of the PMICs 12A and 12B (e.g., PMIC 12A) must switch to generating the modulated voltage V_{CC} based on one of the first parameter set P_{BAND-A} and the second parameter set P_{BAND-B} (e.g., the first parameter set P_{BAND-A}). Concurrently, another one of the PMICs 12A and 12B (e.g., PMIC 12B) must switch to generating the modulated voltage V_{CC} based on another one of the first parameter set P_{BAND-A} and the second parameter set P_{BAND-B} (e.g., second parameter set P_{BAND-B}). Accordingly, each of the PMICs 12A and 12B must load a respective one of the first parameter set P_{BAND-A} and the second parameter set P_{BAND-B} from the respective memory circuit 18 into the parameter clusters 46(1)-46(Y) in the respective register bank 36.

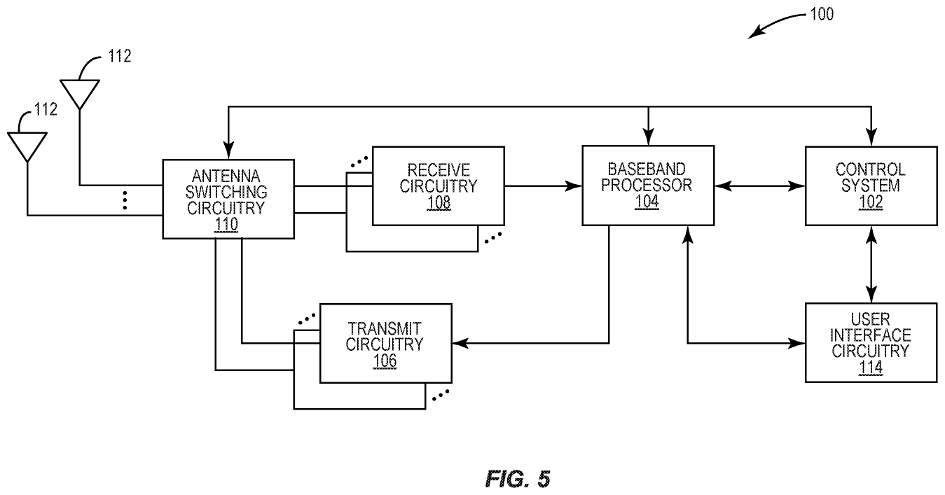

The wireless communication circuit 10 of FIG. 1 and the wireless communication circuit 56 of FIG. 4 can be provided in a communication device to provide beamforming phase correction. FIG. 5 is a schematic diagram of an exemplary communication device 100 wherein the wireless communication circuit 10 of FIG. 1 and the wireless communication circuit 56 of FIG. 4 can be provided.

Herein, the communication device 100 can be any type of communication device, such as mobile terminal, smart watch, tablet, computer, navigation device, access point, base station (e.g., eNB, gNB, etc.), and any other type of wireless communication device that support wireless communications, such as cellular, wireless local area network (WLAN), Bluetooth, Ultra-wideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed on greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110 to the antennas 112. The multiple antennas 112 and the replicated transmit and receive circuitries 106, 108 may provide spatial diversity. Modulation and processing details will be understood by those skilled in the art.

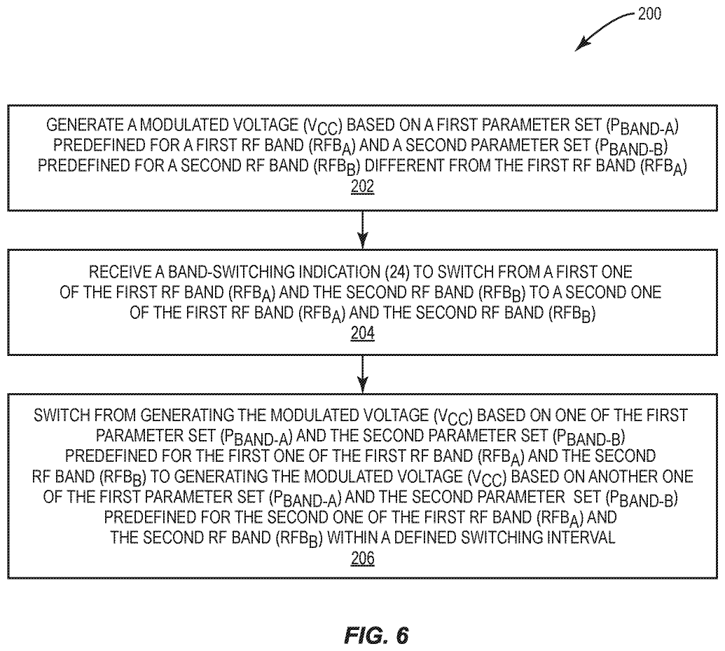

In an embodiment, the wireless communication circuit 10 of FIG. 1 and the wireless communication circuit 56 of FIG. 4 can be configured to switch RF bands according to a process. In this regard, FIG. 6 is a flowchart of an exemplary process 200 for switching RF bands in the wireless communication circuit 10 of FIG. 1 and the wireless communication circuit 56 of FIG. 4.

Herein, the process 200 includes generating the modulated voltage V_{CC} based on the first parameter set P_{BAND-A} predefined for the first RF band RFB_{A} and the second parameter set P_{BAND-B} predefined for the second RF band RFB_{B} different from the first RF band RFB_{A} (step 202). The process 200 also includes receiving the band-switching indication 24 to switch from a first one of the first RF band RFB_{A} and the second RF band RFB_{B} to a second one of the first RF band RFB_{A} and the second RF band RFB_{B} (step 204). The process 200 also includes switching from generating the modulated voltage V_{CC} based on one of the first parameter set P_{BAND-A} and the second parameter set P_{BAND-B} predefined for the first one of the first RF band RFB_{A} and the second RF band RFB_{B} to generating the modulated voltage V_{CC} based on another one of the first parameter set P_{BAND-A} and the second parameter set P_{BAND-B} predefined for the second one of the first RF band RFB_{A} and the second RF band RFB_{B} within a defined switching interval (step 206).

Those skilled in the art will recognize improvements and modifications to the preferred embodiments of the present disclosure. All such improvements and modifications are considered within the scope of the concepts disclosed herein and the claims that follow.

1. A power management integrated circuit (PMIC) comprising:
a voltage processing circuit configured to generate a modulated voltage based on a first parameter set predefined for a first radio frequency (RF) band and a second parameter set predefined for a second RF band different from the first RF band; and
a band-switching circuit configured to:
receive a band-switching indication to switch from a first one of the first RF band and the second RF band to a second one of the first RF band and the second RF band; and
cause the voltage processing circuit to switch from generating the modulated voltage based on one of the first parameter set and the second parameter set predefined for the first one of the first RF band and the second RF band to generating the modulated voltage based on another one of the first parameter set and the second parameter set predefined for the second one of the first RF band and the second RF band within a defined switching interval.

2. The PMIC of claim 1, further comprising:
a first voltage output coupled to a first power amplifier circuit configured to amplify a first RF signal based on the modulated voltage for transmission in the first RF band;
a second voltage output coupled to a second power amplifier circuit configured to amplify a second RF signal based on the modulated voltage for transmission in the second RF band; and
a switch circuit comprising:
a first switch coupled between the voltage processing circuit and the first voltage output; and
a second switch coupled between the voltage processing circuit and the second voltage output.

3. The PMIC of claim 2, wherein the band-switching circuit is further configured to:
receive the band-switching indication during a present orthogonal frequency division multiplexing (OFDM) symbol to switch from the first RF band in the present OFDM symbol to the second RF band in a future OFDM symbol immediately succeeding the present OFDM symbol;
load the second parameter set to the voltage processing circuit prior to a start of the future OFDM symbol; and
close the second switch and open the first switch concurrently at the start of the future OFDM symbol to thereby decouple the voltage processing circuit from the first voltage output and couple the voltage processing circuit to the second voltage output.

4. The PMIC of claim 2, wherein the band-switching circuit is further configured to:
receive the band-switching indication during a present orthogonal frequency division multiplexing (OFDM) symbol to switch from the second RF band in the present OFDM symbol to the first RF band in a future OFDM symbol immediately succeeding the present OFDM symbol;
load the first parameter set to the voltage processing circuit prior to a start of the future OFDM symbol; and
close the first switch and open the second switch concurrently at the start of the future OFDM symbol to thereby decouple the voltage processing circuit from the second voltage output and couple the voltage processing circuit to the first voltage output.

5. The PMIC of claim 2, wherein the band-switching circuit is further configured to:
receive the band-switching indication during a present orthogonal frequency division multiplexing (OFDM) symbol to switch from the first RF band in the present OFDM symbol to the second RF band in a future OFDM symbol separated from the present OFDM symbol by a band-switching gap;
open the first switch at an end of the present OFDM symbol to decouple the voltage processing circuit from the first voltage output;
load the second parameter set to the voltage processing circuit during the band-switching gap; and
close the second switch at a start of the future OFDM symbol to couple the voltage processing circuit to the second voltage output.

6. The PMIC of claim 2, wherein the band-switching circuit is further configured to:
receive the band-switching indication during a present orthogonal frequency division multiplexing (OFDM) symbol to switch from the second RF band in the present OFDM symbol to the first RF band in a future OFDM symbol separated from the present OFDM symbol by a band-switching gap;
open the second switch at an end of the present OFDM symbol to decouple the voltage processing circuit from the second voltage output;
load the first parameter set to the voltage processing circuit during the band-switching gap; and
close the first switch at a start of the future OFDM symbol to couple the voltage processing circuit to the first voltage output.

7. The PMIC of claim 1, further comprising an RF front-end (RFFE) interface coupled to a transceiver circuit to receive the band-switching indication from the transceiver circuit.

8. The PMIC of claim 7, wherein the band-switching circuit comprises:
a memory circuit preloaded with the first parameter set and the second parameter set;
a register bank configured to:
store the first parameter set when the voltage processing circuit is configured to generate the modulated voltage for the first RF band; and
store the second parameter set when the voltage processing circuit is configured to generate the modulated voltage for the second RF band; and
a memory controller configured to:
load the second parameter set from the memory circuit to the register bank in response to receiving the band-switching indication to switch from the first RF band to the second RF band; and
load the first parameter set from the memory circuit to the register bank in response to receiving the band-switching indication to switch from the second RF band to the first RF band.

9. The PMIC of claim 8, wherein the band-switching circuit further comprises an RFFE circuit configured to receive the first parameter set and the second parameter set from the transceiver circuit based on an RFFE extended register read/write command sequence.

10. A wireless device comprising:
one or more power management integrated circuits, (PMICs) each comprising:
a voltage processing circuit configured to generate a modulated voltage based on a first parameter set predefined for a first radio frequency (RF) band and a second parameter set predefined for a second RF band different from the first RF band; and
a band-switching circuit configured to:
receive a band-switching indication to switch from a first one of the first RF band and the second RF band to a second one of the first RF band and the second RF band; and
cause the voltage processing circuit to switch from generating the modulated voltage based on one of the first parameter set and the second parameter set predefined for the first one of the first RF band and the second RF band to generating the modulated voltage based on another one of the first parameter set and the second parameter set predefined for the second one of the first RF band and the second RF band within a defined switching interval.

11. The wireless device of claim 10, wherein each of the one or more PMICs further comprises:
a first voltage output coupled to a first power amplifier circuit configured to amplify a first RF signal based on the modulated voltage for transmission in the first RF band;
a second voltage output coupled to a second power amplifier circuit configured to amplify a second RF signal based on the modulated voltage for transmission in the second RF band; and
a switch circuit comprising:
a first switch coupled between the voltage processing circuit and the first voltage output; and
a second switch coupled between the voltage processing circuit and the second voltage output.

12. The wireless device of claim 11, wherein the band-switching circuit is further configured to:
receive the band-switching indication during a present orthogonal frequency division multiplexing (OFDM) symbol to switch from the first RF band in the present OFDM symbol to the second RF band in a future OFDM symbol immediately succeeding the present OFDM symbol;
load the second parameter set to the voltage processing circuit prior to a start of the future OFDM symbol; and
close the second switch and open the first switch concurrently at the start of the future OFDM symbol to thereby decouple the voltage processing circuit from the first voltage output and couple the voltage processing circuit to the second voltage output.

13. The wireless device of claim 11, wherein the band-switching circuit is further configured to:
receive the band-switching indication during a present orthogonal frequency division multiplexing (OFDM) symbol to switch from the second RF band in the present OFDM symbol to the first RF band in a future OFDM symbol immediately succeeding the present OFDM symbol;
load the first parameter set to the voltage processing circuit prior to a start of the future OFDM symbol; and
close the first switch and open the second switch concurrently at the start of the future OFDM symbol to thereby decouple the voltage processing circuit from the second voltage output and couple the voltage processing circuit to the first voltage output.

14. The wireless device of claim 11, wherein the band-switching circuit is further configured to:
receive the band-switching indication during a present orthogonal frequency division multiplexing (OFDM) symbol to switch from the first RF band in the present OFDM symbol to the second RF band in a future OFDM symbol separated from the present OFDM symbol by a band-switching gap;
open the first switch at an end of the present OFDM symbol to decouple the voltage processing circuit from the first voltage output;
load the second parameter set to the voltage processing circuit during the band-switching gap; and
close the second switch at a start of the future OFDM symbol to couple the voltage processing circuit to the second voltage output.

15. The wireless device of claim 11, wherein the band-switching circuit is further configured to:
receive the band-switching indication during a present orthogonal frequency division multiplexing (OFDM) symbol to switch from the second RF band in the present OFDM symbol to the first RF band in a future OFDM symbol separated from the present OFDM symbol by a band-switching gap;
open the second switch at an end of the present OFDM symbol to decouple the voltage processing circuit from the second voltage output;
load the first parameter set to the voltage processing circuit during the band-switching gap; and
close the first switch at a start of the future OFDM symbol to couple the voltage processing circuit to the first voltage output.

16. The wireless device of claim 10, wherein each of the one or more PMICs further comprises an RF front-end (RFFE) interface coupled to a transceiver circuit to receive the band-switching indication from the transceiver circuit.

17. The wireless device of claim 16, wherein the band-switching circuit comprises:
a memory circuit preloaded with the first parameter set and the second parameter set;
a register bank configured to:
store the first parameter set when the voltage processing circuit is configured to generate the modulated voltage for the first RF band; and
store the second parameter set when the voltage processing circuit is configured to generate the modulated voltage for the second RF band; and
a memory controller configured to:
load the second parameter set from the memory circuit to the register bank in response to receiving the band-switching indication to switch from the first RF band to the second RF band; and
load the first parameter set from the memory circuit to the register bank in response to receiving the band-switching indication to switch from the second RF band to the first RF band.

18. The wireless device of claim 17, wherein the band-switching circuit further comprises an RFFE circuit configured to receive the first parameter set and the second parameter set from the transceiver circuit based on an RFFE extended register read/write command sequence.

19. The wireless device of claim 10, further comprising:
a transceiver circuit coupled to each of the one or more PMICs and configured to provide the band-switching indication to each of the one or more PMICs; and
one or more pairs of power amplifier circuits, each coupled to a respective one of the one or more PMICs, each pair of power amplifier circuits is configured to amplify a respective one of a first RF signal and a second RF signal for transmission in a respective one of the first RF band and the second RF band.

20. A method for switching radio frequency bands in a wireless device comprising:
generating a modulated voltage based on a first parameter set predefined for a first RF band and a second parameter set predefined for a second RF band different from the first RF band;
receiving a band-switching indication to switch from a first one of the first RF band and the second RF band to a second one of the first RF band and the second RF band; and
switching from generating the modulated voltage based on one of the first parameter set and the second parameter set predefined for the first one of the first RF band and the second RF band to generating the modulated voltage based on another one of the first parameter set and the second parameter set predefined for the second one of the first RF band and the second RF band within a defined switching interval.
